(19) United States
(12) Patent Application Publication
(10) Pub. No.: US 2024/0113507 A1
(43) Pub. Date: Apr. 4, 2024

(54) SURFACE EMITTING QUANTUM CASCADE LASER AND CONTROL METHOD THEREOF

(71) Applicant: KABUSHIKI KAISHA TOSHIBA, Tokyo (JP)

(72) Inventors: Rei HASHIMOTO, Edogawa Tokyo (JP); Shinji SAITO, Yokohama Kanagawa (JP); Tsutomu KAKUNO, Fujisawa Kanagawa (JP); Kei KANEKO, Yokohama Kanagawa (JP)

(21) Appl. No.: 18/479,706

(22) Filed: Oct. 2, 2023

(30) Foreign Application Priority Data
Oct. 3, 2022 (JP) 2022-159544

(51) Int. Cl. H01S 5/18; H01S 5/065; H01S 5/34

(52) U.S. Cl. CPC H01S 5/18; H01S 5/065; H01S 5/34

(57) ABSTRACT

According to one embodiment, a surface emitting quantum cascade laser includes: a first surface that emits laser light; a second surface opposite to the first surface; an active layer provided between the first surface and the second surface; a photonic crystal provided between the active layer and the first surface or between the active layer and the second surface, the photonic crystal having a predetermined periodicity; a first electrode located on the first surface outside a region where the laser light is emitted; a second electrode provided on the second surface, the photonic crystal being located between the first surface and the second electrode; and a third electrode provided on the second surface and separated from the second electrode, the active layer extending between the first surface and the second electrode and between the first surface and the third electrode.

### CROSS-REFERENCE TO RELATED APPLICATIONS

This application is based upon and claims the benefit of priority from Japanese Patent Application No. 2022-159544, filed on Oct. 3, 2022; the entire contents of which are incorporated herein by reference.

### FIELD

Embodiments described herein relate generally to a surface emitting quantum cascade laser and a control method thereof.

### BACKGROUND

A surface emitting quantum cascade laser includes a photonic crystal that controls laser oscillation, and can achieve single-mode oscillation. However, a sub-mode that does not depend on the photonic crystal may occur.

### BRIEF DESCRIPTION OF THE DRAWINGS

FIG. 1 is a schematic cross-sectional view showing a quantum cascade laser 1 according to the embodiment;

FIG. 2 is a schematic cross-sectional view showing the active layer 30 of the quantum cascade laser 1 according to the embodiment;

FIGS. 3A to 3C are schematic views showing energy bands of the active layer 30 according to the embodiment;

FIGS. 4A and 4B are schematic views showing oscillation spectra of the quantum cascade laser 1 according to the embodiment;

FIGS. 5A to 5C are schematic plan views showing a reflection-surface-side electrode of the quantum cascade laser 1 according to the embodiment;

FIGS. 6A to 6C are schematic plan views showing a reflection-surface-side electrode according to a variation of the embodiment;

FIGS. 7A and 7B are schematic plan views showing a reflection-surface-side electrode according to another variation of the embodiment;

FIGS. 8A to 8C are schematic plan views showing the light- emitting surface LS of the quantum cascade laser 1 according to the embodiment; and

FIGS. 9A to 9C are schematic plan views showing the light-emitting surface LS of the quantum cascade laser 1 according to a variation of the embodiment.

### DETAILED DESCRIPTION

According to one embodiment, a surface emitting quantum cascade laser includes: a first surface that emits laser light; a second surface opposite to the first surface; an active layer provided between the first surface and the second surface; a photonic crystal provided between the active layer and the first surface or between the active layer and the second surface, the photonic crystal having a predetermined periodicity; a first electrode located on the first surface outside a region where the laser light is emitted; a second electrode provided on the second surface, the photonic crystal being located between the first surface and the second electrode; and a third electrode provided on the second surface and separated from the second electrode, the active layer extending between the first surface and the second electrode and between the first surface and the third electrode.

The embodiment provides a surface emitting quantum cascade laser that oscillates in a single mode and a control method thereof.

Hereinafter, an embodiment will be described with reference to the drawings. A detailed description of the same portion in the drawings attached with the same reference sign will be omitted as appropriate, and a different portion will be described. The drawings are schematic or conceptual. A relationship between a thickness and a width of each portion, a ratio of sizes between portions, and the like are not necessarily the same as the actual ones. Even when the same portions are shown, dimensions and ratios may be shown differently from each other in the drawings.

Next, an arrangement and a configuration of each part will be described using an X axis, a Y axis, and a Z axis shown in each drawing. The X axis, the Y axis, and the Z axis are orthogonal to one another and separately represent an X-direction, a Y-direction, and a Z-direction. The Z-direction may be described as an upper side, and an opposite direction of the Z-direction may be described as a lower side.

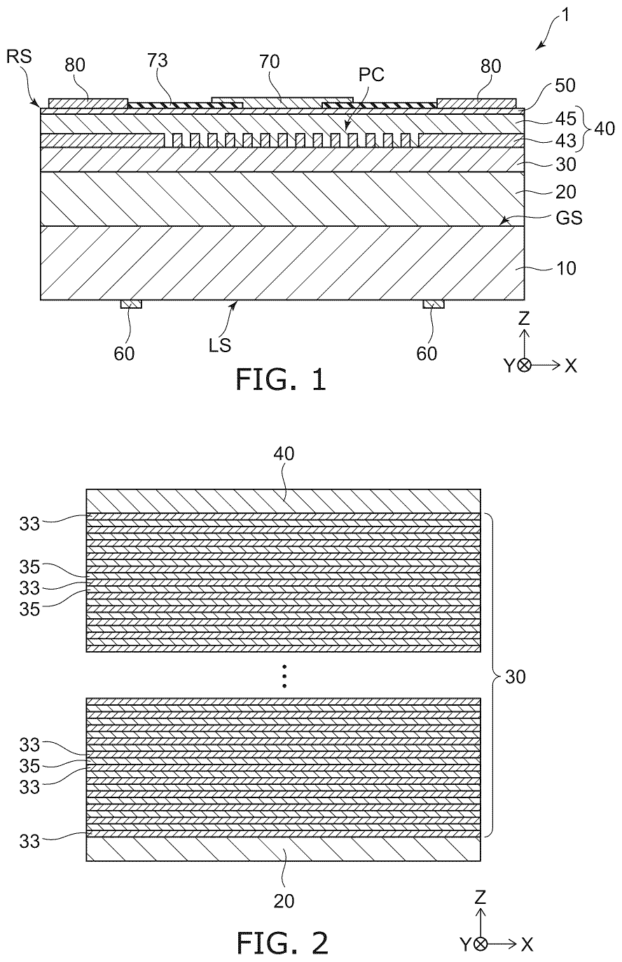

FIG. 1 is a schematic cross-sectional view showing a quantum cascade laser 1 according to the embodiment. The quantum cascade laser 1 is a surface emitting quantum cascade laser. Here, surface emitting is a concept distinguished from an end face emitting in which laser light is emitted from an end of an active layer, and means a mode in which laser light, for example, propagates in a direction from an active layer toward a semiconductor substrate or in a reverse direction thereof and is emitted from a back surface of the semiconductor substrate or a surface of a growth layer on the semiconductor substrate.

The quantum cascade laser 1 includes a semiconductor substrate 10, a first semiconductor layer 20, an active layer 30, a second semiconductor layer 40, and a contact layer 50. The first semiconductor layer 20, the active layer 30, the second semiconductor layer 40, and the contact layer 50 are epitaxially grown at the semiconductor substrate 10 using, for example, molecular beam epitaxy (MBE).

The semiconductor substrate 10 is, for example, an n-type InP substrate. The semiconductor substrate 10 has a light-emitting surface LS and an epitaxial growth surface GS. The epitaxial growth surface GS is opposite to the light-emitting surface LS.

The first semiconductor layer 20 is, for example, an n-type InP layer. The first semiconductor layer 20 is provided on the epitaxial growth surface GS of the semiconductor substrate 10.

The active layer 30 is provided on the first semiconductor layer 20. The active layer 30 has, for example, a multiple quantum well structure.

The second semiconductor layer 40 is provided on the active layer 30. The second semiconductor layer 40 includes a photonic crystal PC.

The second semiconductor layer 40 includes, for example, a first layer 43 and a second layer 45. The first layer 43 is provided on the active layer 30, and the second layer 45 is provided on the first layer 43. The first layer 43 includes, for example, a ternary compound InGaAs represented by a composition formula InₓGa₁₋ₓAs (0<×<1). The first layer 43 is an n-type InGaAs layer. An InGaAs layer has, for example, a composition x lattice-matching with InP. The second layer 45 is, for example, an n-type InP layer.

The first layer 43 includes, for example, multiple convex portions periodically provided on a second layer 45 side, and the second layer 45 embeds the multiple convex portions of the first layer 43. The photonic crystal PC includes the convex portions of the first layer 43 and the second layer 45. The photonic crystal PC has a structure in which a refractive index periodically changes in a direction along an interface between the active layer 30 and the second semiconductor layer 40.

The contact layer 50 is provided on the second semiconductor layer 40. The contact layer 50 is, for example, an n-type InGaAs layer. The contact layer 50 has an energy band gap narrower than an energy band gap of the second layer 45 of the second semiconductor layer 40.

The quantum cascade laser 1 further includes a first electrode 60, a second electrode 70, and a third electrode 80. The first electrode 60 is provided on the light-emitting surface LS of the semiconductor substrate 10. The second electrode 70 and the third electrode 80 are provided on a reflection surface RS opposite to the light-emitting surface LS. Here, the reflection surface RS is a surface of the contact layer 50. The active layer 30 is located between the light-emitting surface LS (first surface) and the reflection surface RS (second surface).

The first electrode 60 is provided, for example, outside a light-emitting region on the light-emitting surface LS. The first electrode 60 has, for example, a two-layer structure including titanium (Ti) and gold (Au).

The second electrode 70 is provided on the contact layer 50. For example, the second electrode 70 contacts the contact layer 50 via a contact hole of an insulating film 73 provided on the contact layer 50. The second electrode 70 includes a portion in contact with the contact layer 50 and a portion provided on the insulating film 73. The insulating film 73 is, for example, a silicon oxide film. The second electrode 70 includes, for example, Au, and reflects light emitted from the active layer 30.

For example, the second electrode 70 has an area smaller than an area of the photonic crystal PC in a plane parallel to the reflection surface RS. That is, in a plan view parallel to the reflection surface RS, the photonic crystal PC has a portion located immediately below the second electrode 70 and a portion located outside the second electrode 70.

The third electrode 80 is provided on the contact layer 50 to be separated from the second electrode 70. The third electrode 80 contains, for example, the same material as the second electrode 70 and reflects light emitted from the active layer 30.

The active layer 30 extends between the light-emitting surface LS and the second electrode 70 and between the light-emitting surface LS and the third electrode 80. The photonic crystal PC is provided between the light-emitting surface LS and the second electrode 70. The photonic crystal PC may not be provided between the light-emitting surface LS and the third electrode 80, for example.

The embodiment is not limited to the above example. For example, the photonic crystal PC may be provided in the first semiconductor layer 20. Laser light may be emitted from a surface side of the contact layer 50. In this case, the first electrode 60 is provided on the surface of the contact layer 50, and the second electrode 70 and the third electrode 80 are provided on a back surface of the semiconductor substrate 10.

FIG. 2 is a schematic cross-sectional view showing the active layer 30 of the quantum cascade laser 1 according to the embodiment. The active layer 30 includes multiple barrier layers 33 and multiple quantum well layers 35. The barrier layers 33 and the quantum well layers 35 are alternately stacked in a direction from the first semiconductor layer 20 toward the second semiconductor layer 40, for example, in the Z-direction. Each of the quantum well layers 35 is located between adjacent barrier layers 33. Each of the barrier layers 33 includes, for example, a ternary compound AlInAs represented by a composition formula Al_{y}In_{1-y}As (0<y<1). The quantum well layer 35 includes InGaAs.

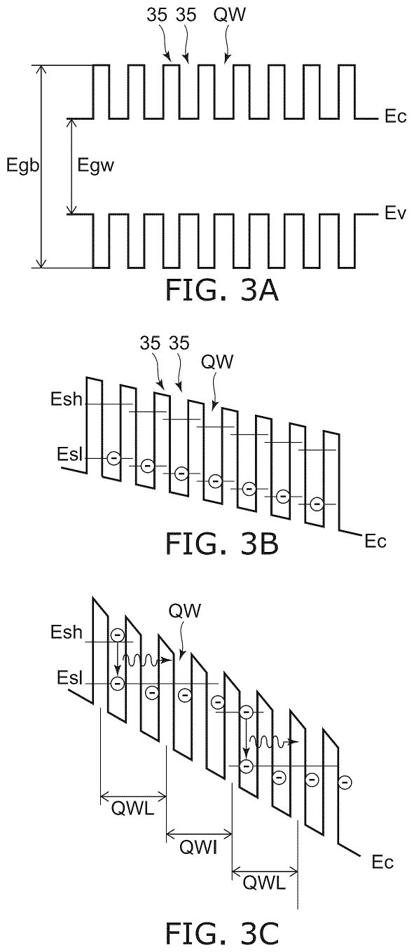

FIGS. 3A to 3C are schematic views showing energy bands of the active layer 30 according to the embodiment. FIG. 3A shows an energy band structure of the active layer 30 in a thermal equilibrium state. FIGS. 3B and 3C show a conduction band Ec of the active layer 30 under a predetermined bias.

As shown in FIG. 3A, the barrier layer 33 has an energy band gap Egb between a valence band Ev and the conduction band Ec. On the other hand, the quantum well layer 35 has an energy band gap Egw narrower than the energy band gap Egb. The valence band Ev and the conduction band Ec each have a quantum well QW caused by an energy difference between the energy band gap Egb and the energy band gap Egw.

FIG. 3B shows the conduction band Ec of the active layer 30 biased by a voltage lower than a threshold voltage of laser oscillation. Electrons injected into the active layer 30 are distributed in the quantum well QW of the conduction band Ec. The electrons in the active layer 30 are distributed in, for example, a subband Es1 in a ground state.

FIG. 3C shows the conduction band Ec of the active layer 30 biased by a voltage higher than the threshold voltage. As shown in FIG. 3C, the active layer 30 includes a light-emitting quantum well QWE and an injection quantum well QWI.

The electrons injected into the active layer 30 are accelerated by an electric field and excited to a subband Esh having higher energy than the subband Esl. Further, the excited electrons transit from the subband Esh to the subband Esl in the light-emitting quantum well QWE, and light is emitted. The electrons that transitioned to the subband Esl move in the injection quantum well QWI by an electric field, are excited during the movement, and transition from the subband Esh to the subband Esl in the next light-emitting quantum well QWE. Accordingly, light is emitted again. By repeating this process in the active layer 30, light is emitted more efficiently, leading to laser oscillation.

In the quantum cascade laser 1, a voltage higher than the threshold voltage of laser oscillation is applied between the first electrode 60 and the second electrode 70. On the other hand, a voltage lower than the threshold voltage is applied between the first electrode 60 and the third electrode 80.

In the active layer 30 between the first electrode 60 and the second electrode 70, laser oscillation controlled by the photonic crystal PC occurs, and the laser light propagates in a direction of the light- emitting surface LS and the reflection surface RS (see FIG. 1). The laser light propagating in the direction of the reflection surface RS is reflected by the second electrode 70, and a propagation direction thereof is reversed to a direction toward the light-emitting surface. Accordingly, the laser light is emitted to an outside from the light-emitting surface LS.

In the active layer 30 located between the first electrode 60 and the third electrode 80, a light absorption region in which electrons are distributed at high density is formed without reaching laser oscillation. Therefore, for example, it is possible to prevent laser oscillation in a Fabry-Perot mode caused by end face reflection of light propagating in a direction parallel to the interface between the active layer 30 and the second semiconductor layer 40.

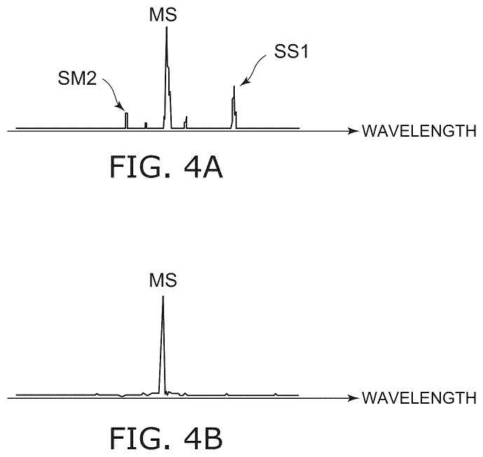

FIGS. 4A and 4B are schematic views showing oscillation spectra of the quantum cascade laser 1 according to the embodiment.

FIG. 4A shows an oscillation spectrum when a voltage higher than the threshold voltage is applied between the first electrode 60 and the second electrode 70 and no voltage is applied between the first electrode 60 and the third electrode 80.

FIG. 4B shows an oscillation spectrum when a voltage higher than the threshold voltage is applied between the first electrode 60 and the second electrode 70 and a voltage lower than the threshold voltage is applied between the first electrode 60 and the third electrode 80.

The oscillation spectrum shown in FIG. 4A includes a main mode MS and sub-modes SS1 and SS2. The main mode MS is an oscillation mode controlled by the photonic crystal PC. The sub-modes SS1 and SS2 are Fabry-Perot modes caused by end face reflection of the active layer 30.

On the other hand, in the oscillation spectrum shown in FIG. 4B, the sub-modes SS1 and SS2 disappear, and the main mode MS remains. That is, single-mode oscillation controlled by the photonic crystal PC is obtained.

Thus, in the quantum cascade laser 1, by applying a voltage lower than the threshold voltage of laser oscillation between the first electrode 60 and the third electrode 80, the light absorption region is formed inside the active layer 30, and oscillation in the Fabry-Perot mode can be prevented.

For example, by increasing a distance between a portion of the active layer 30 located under the photonic crystal PC and an end face of the active layer 30, light absorption in the active layer 30 can be increased without providing the third electrode 80. Accordingly, it is also possible to prevent the Fabry-Perot mode.

For example, in a laser using light emission due to interband transition between a valence band and a conduction band, an active layer serves as a light emission absorber, but light absorption of the active layer 30 in the quantum cascade laser can be ignored. However, even in a case of the quantum cascade laser, there is generally negligible light absorption such as light absorption caused by an impurity level or the like. Therefore, when a propagation distance of the light in the active layer 30 is long, attenuation of the light is a non-negligible level. For example, when a separation distance between the portion of the active layer 30 located under the photonic crystal PC and the end face of the active layer 30 is 100 μm or longer, the Fabry-Perot mode can be prevented by light absorption caused by impurities and the like contained therebetween. Further, as the separation distance increases, the light absorption increases, and an effect of preventing the Fabry-Perot mode increases. For example, by providing a separation distance of 500 μm or more, an effect of preventing a multimode of the laser oscillation near an oscillation threshold value current can be expected. In addition, by setting the separation distance to 1000 μm or more, a further effect can be expected, and the Fabry-Perot mode can be prevented even in an injection current region that greatly exceeds the oscillation threshold value current.

On the other hand, in such a configuration, there is also a disadvantage that a chip size increases and manufacturing cost increases. In addition, a size of a device including the quantum cascade laser also increases. Therefore, in the quantum cascade laser 1 according to the embodiment, single-mode oscillation is implemented while reducing a size of a laser chip by providing the third electrode 80.

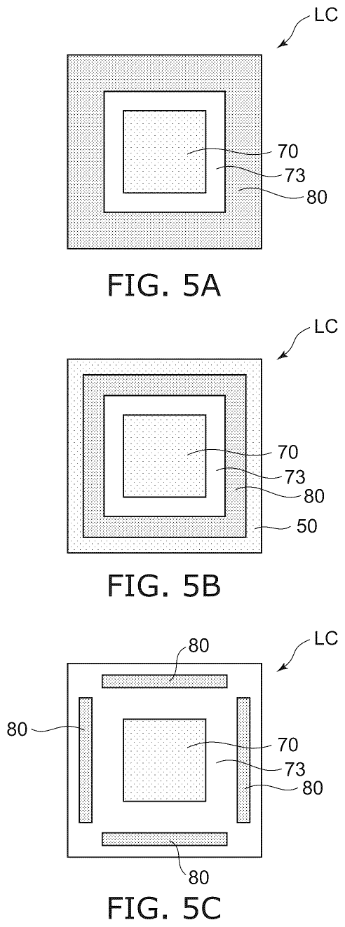

FIGS. 5A to 5C are schematic plan views showing a reflection-surface-side electrode of the quantum cascade laser 1 according to the embodiment. The second electrode 70 is provided at a center of a laser chip LC. The third electrode 80 is separated from the second electrode 70 and surrounds the second electrode 70.

In an example shown in FIG. 5A, for example, the third electrode 80 covers an entire chip surface except for a laser oscillation region in the plan view. Accordingly, an area of the light absorption region formed in the active layer 30 can be maximized.

In an example shown in FIG. 5B, the third electrode 80 is not provided on a dicing region along an outer edge of the laser chip LC. Accordingly, it is easy to cut out the laser chip from a wafer. It is possible to avoid peeling of the third electrode 80 in a dicing process of the laser chip LC and to improve a manufacturing yield.

In an example shown in FIG. 5C, the third electrode 80 is not provided on a diagonal line connecting two of four corners of the laser chip LC. Oscillation in the Fabry-Perot mode is caused by multiple reflection between opposite end faces of the active layer 30. Therefore, the Fabry-Perot mode caused by light propagating in a diagonal direction of the laser chip LC can be ignored. Therefore, a portion of the third electrode 80 located on the diagonal line can be removed. The third electrode 80 having such a configuration can be formed by, for example, a vapor deposition method using a metal mask.

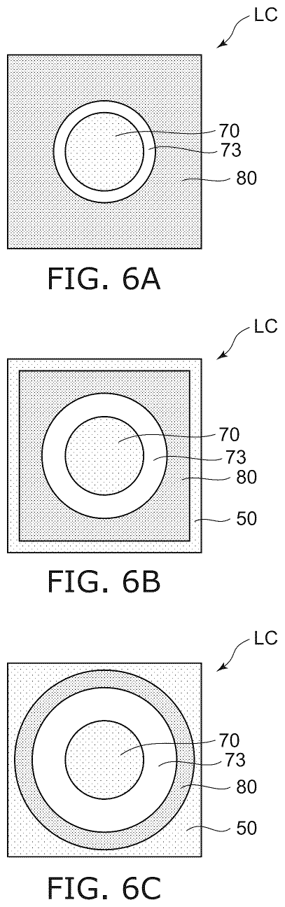

FIGS. 6A to 6C are schematic plan views showing a reflection-surface-side electrode according to a variation of the embodiment. In these examples, the second electrode 70 is provided at a center of the laser chip LC and has, for example, a circular shape. A planar shape of the second electrode 70 can be freely set, and may be, for example, a polygon. The third electrode 80 is separated from the second electrode 70 and surrounds the second electrode 70.

As shown in FIG. 6A, the third electrode 80 covers the entire chip surface except for a laser oscillation region in the plan view. The third electrode 80 is provided at an equal distance from the second electrode 70.

As shown in FIG. 6B, the third electrode 80 is not provided in the dicing region along the outer edge of the laser chip LC.

As shown in FIG. 6C, the third electrode 80 has a constant width in a direction from a center toward the outer edge of the laser chip LC.

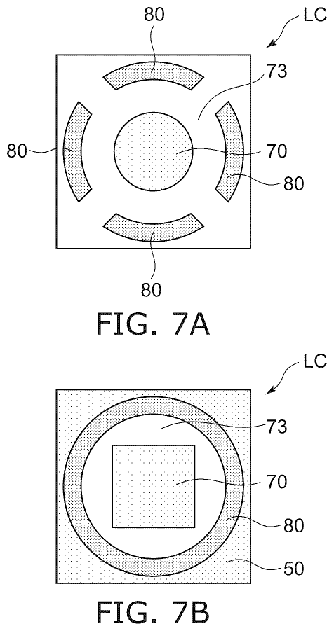

FIGS. 7A and 7B are schematic plan views showing a reflection-surface-side electrode according to another variation of the embodiment. The second electrode 70 is provided at the center of the laser chip LC. The third electrode 80 is separated from the second electrode 70 and surrounds the second electrode 70.

In an example shown in FIG. 7A, the second electrode 70 has a circular planar shape. The third electrode 80 has a constant width in the direction from the center toward the outer edge of the laser chip LC. Further, the third electrode 80 is not provided on the diagonal line connecting two of the four corners of the laser chip LC.

In an example shown in FIG. 7B, the second electrode 70 has a square planar shape. The third electrode 80 has a circular outer edge and has a constant width in the direction from the center toward the outer edge of the laser chip LC.

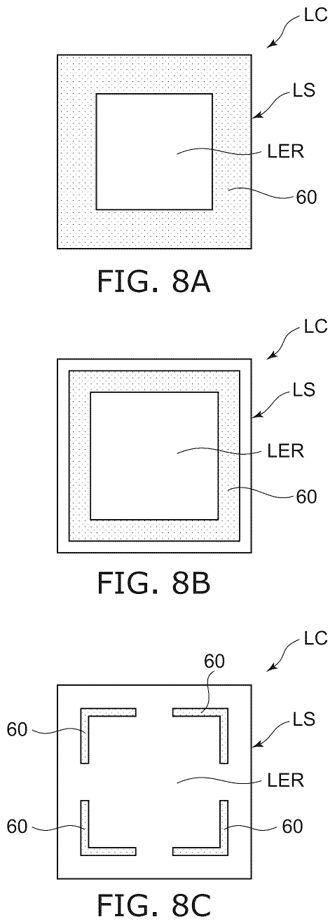

FIGS. 8A to 8C are schematic plan views showing the light-emitting surface LS of the quantum cascade laser 1 according to the embodiment. The first electrode 60 is provided on the light-emitting surface LS to surround a light-emitting region LER.

In an example shown in FIG. 8A, the first electrode 60 covers the entire light-emitting surface LS except for the light-emitting region LER.

As shown in FIG. 8B, the first electrode 60 is not provided in the dicing region along the outer edge of the laser chip LC.

As shown in FIG. 8C, the first electrode 60 may have multiple portions separated from each other. Accordingly, the first electrode 60 can be formed by, for example, a vapor deposition method using a metal mask.

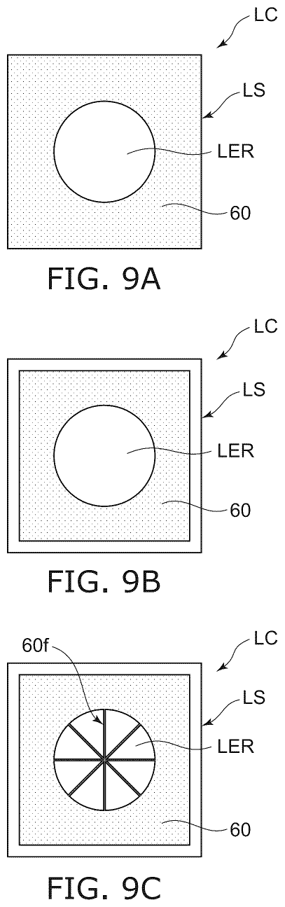

FIGS. 9A to 9C are schematic plan views showing the light-emitting surface LS of the quantum cascade laser 1 according to a variation of the embodiment. The first electrode 60 is provided on the light-emitting surface LS to surround the circular light-emitting region LER. A planar shape of the light-emitting region LER can be freely set, and may be, for example, a polygon.

As shown in FIG. 9A, the first electrode 60 covers the entire light-emitting surface LS except for the circular light-emitting region LER.

As shown in FIG. 9B, the first electrode 60 is not provided in the dicing region along the outer edge of the laser chip LC.

As shown in FIG. 9B, the first electrode 60 includes a thin wire electrode 60f provided in the light-emitting region LER. By providing the thin wire electrode 60f, electrons injected into the active layer 30 can be made uniform, and luminous efficiency can be improved.

While certain embodiments are described, these embodiment are presented as examples and are not intended to limit the scope of the invention. These novel embodiments can be implemented in various other forms, and various omissions, substitutions, and changes can be made without departing from the spirit of the invention. The embodiments and the variations thereof are in the scope and the spirit of the invention and are also in the invention described in the scope of claims and an equivalent scope thereof.

The embodiments may include the following configurations (for example, technical proposals).

### CONFIGURATION 1

A surface emitting quantum cascade laser comprising:
a first surface that emits laser light;
a second surface opposite to the first surface;
an active layer provided between the first surface and the second surface;
a photonic crystal provided between the active layer and the first surface or between the active layer and the second surface, the photonic crystal having a predetermined periodicity; a first electrode located on the first surface outside a region where the laser light is emitted;
a second electrode provided on the second surface, the photonic crystal being located between the first surface and the second electrode; and
a third electrode provided on the second surface and separated from the second electrode, the active layer extending between the first surface and the second electrode and between the first surface and the third electrode.

### CONFIGURATION 2

The laser according to Configuration 1, wherein
in a direction parallel to a surface of the active layer that faces the photonic crystal, the photonic crystal has a refractive index with respect to the laser light that changes with the periodicity.

### CONFIGURATION 3

The laser according to Configurations 1 or 2, wherein
the photonic crystal is not provided between the first surface and the third electrode.

### CONFIGURATION 4

The laser according to one of Configurations 1 to 3, further comprising:

a first semiconductor layer provided between the first surface and the active layer; and
a second semiconductor layer provided between the second surface and the active layer,
the photonic crystal being provide in one of the first semiconductor layer and the second semiconductor layer.

### CONFIGURATION 5

The laser according to Configuration 4, wherein
the photonic crystal has a first area in a plane parallel to a boundary between the first semiconductor layer and the active layer, and
the second electrode has a second area smaller than the first area in the plane.

### CONFIGURATION 6

A method for controlling the laser according to any one of Configurations 1 to 5, the method comprising:
applying a voltage higher than an oscillation threshold voltage of the surface emitting quantum cascade laser between the first electrode and the second electrode; and
applying a voltage lower than the oscillation threshold voltage between the first electrode and the third electrode.

What is claimed is:

1. A surface emitting quantum cascade laser comprising:
a first surface that emits laser light;
a second surface opposite to the first surface;
an active layer provided between the first surface and the second surface;
a photonic crystal provided between the active layer and the first surface or between the active layer and the second surface, the photonic crystal having a predetermined periodicity;
a first electrode located on the first surface outside a region where the laser light is emitted;
a second electrode provided on the second surface, the photonic crystal being located between the first surface and the second electrode; and
a third electrode provided on the second surface and separated from the second electrode, the active layer extending between the first surface and the second electrode and between the first surface and the third electrode.

2. The laser according to claim 1, wherein
in a direction parallel to a surface of the active layer that faces the photonic crystal, the photonic crystal has a refractive index with respect to the laser light that changes with the periodicity.

3. The laser according to claim 1, wherein
the photonic crystal is not provided between the first surface and the third electrode.

4. The laser according to claim 1, further comprising:
a first semiconductor layer provided between the first surface and the active layer; and
a second semiconductor layer provided between the second surface and the active layer,
the photonic crystal being provide in one of the first semiconductor layer and the second semiconductor layer.

5. The laser according to claim 4, wherein
the photonic crystal has a first area in a plane parallel to a boundary between the first semiconductor layer and the active layer, and
the second electrode has a second area smaller than the first area in the plane.

6. A method for controlling the laser according to claim 1, the method comprising:
applying a voltage higher than an oscillation threshold voltage of the surface emitting quantum cascade laser between the first electrode and the second electrode; and
applying a voltage lower than the oscillation threshold voltage between the first electrode and the third electrode.

7. A surface emitting quantum cascade laser comprising:
a first surface that emits laser light;
a second surface opposite to the first surface;
an active layer provided between the first surface and the second surface;
a photonic crystal provided between the active layer and the first surface or between the active layer and the second surface, the photonic crystal having a predetermined periodicity;
a first electrode located on the first surface outside a region where the laser light is emitted; and
a second electrode provided on the second surface, the photonic crystal being located between the first surface and the second electrode,
in a direction along a surface of the active layer that faces the photonic crystal, the photonic crystal being separated from a position of an end of the active layer, a separation distance being sufficient to prevent oscillation in a Fabry-Perot mode.
